(19) United States
(12) Patent Application Publication
(10) Pub. No.: US 2007/0210365 A1
(43) Pub. Date: Sep. 13, 2007

(54) SEMICONDUCTOR DEVICE AND METHOD FOR MANUFACTURING THE SAME

(75) Inventors: Yuki TOGASHI, Tokyo (JP); Hiroyuki KITAMURA, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 11/679,386

(22) Filed: Feb. 27, 2007

(30) Foreign Application Priority Data
Mar. 9, 2006 (JP) 2006-064108

(51) Int. Cl. H01L 29/00

(52) U.S. Cl. 257/296; 257/516

(57) ABSTRACT

A semiconductor device includes a cylindrical capacitor. A size of hemispherical silicon grains (HSGs) formed in a straight portion of the cylindrical capacitor is smaller than a size of HSGs formed in a bowing portion of the cylindrical capacitor.

This application claims priority to prior Japanese patent application JP 2006-64108, the disclosure of which is incorporated herein by reference.

### BACKGROUND OF THE INVENTION

1. Field of the Invention

The present invention relates to a semiconductor device and a method for manufacturing the semiconductor device, and more particularly to a semiconductor device having a cylindrical capacitor and a method for manufacturing the semiconductor device.

2. Description of the Related Art

Recently, semiconductor devices are becoming large-scale. In a dynamic random access memory (DRAM), a large 1 GB memory has been developed. A DRAM cell is composed of one gate transistor and one capacitor. The amount of electric charge stored in the capacitor serves as information. Electric charges are exchanged through the gate transistor. Thus, stable operation of the DRAM requires a certain capacitance. However, an increase in storage capacity causes a decrease in memory cell area and accordingly a decrease in the effective area of a cell capacitor. Thus, various methods have been devised to ensure a sufficient cell capacitance in such a small area.

Examples of the methods adopted include methods for increasing an electrode area of a capacitor using a capacitor over bit line (COB) structure, in which a cell capacitor is disposed over a bit line, or a hemispherical silicon grain (HSG) structure and methods using a high-dielectric film. As the high-dielectric film, use is made of tantalum oxide (Ta₂O₅) films having a dielectric constant several times higher than existing silicon oxide films or silicon nitride films. These technologies have been combined to provide a semiconductor device having a large storage capacity.

Hereinbelow, description will be made of a method for manufacturing these cell capacitors. In the COB structure, a capacitor hole for forming a cylindrical cell capacitor is bored or opened in an interlayer insulating film over a bit line. The capacitor hole is connected to a diffusion layer of a cell transistor via a polysilicon plug. An amorphous silicon film is deposited in the capacitor hole as a lower electrode of the capacitor. The amorphous silicon film is heat-treated in an atmosphere of SiH₄ or Si₂H₆ for seeding. Subsequently, the amorphous silicon film is heat-treated under high vacuum to roughen the surface thereof (to form HSG). By the heat treatment, the migration of silicon atoms occurs during crystallization around the seeded silicon atoms. The migration allows the silicon atoms to grow as hemispherical silicon grains (HSGs).

In this case, a high-concentration impurity, such as phosphorus (P) atoms, in the amorphous silicon inhibits the migration of silicon atoms. Consequently, the sufficient growth of silicon grains is avoided. Therefore, HSGs are generally grown in the presence of about 1 to 2×10²⁰ atoms/cm³ or less of impurities to roughen the surface of the amorphous silicon film. When impurities are electrically insufficient, the amorphous silicon film may be heat-treated again, for example, in a PH₃ atmosphere to introduce phosphorus atoms into the silicon film to thereby increase impurities. This method can almost double the silicon surface area. Thus, the silicon surface area can be increased while the effective area of the cell capacitor is decreased.

The following Patent Documents describe improvements of cell capacitors. Japanese Unexamined Patent Application Publications Nos. 2002-368133 and 2000-196042 disclose techniques for preventing the growth of HSGs at the upper end of a cylindrical electrode, at which an HSG silicon layer is liable to detach, by implanting ions into the upper end to increase impurities. In Japanese Unexamined Patent Application Publication No. 2003-124348, a high-dielectric film is applied to a cylindrical capacitor or a crown capacitor. Japanese Unexamined Patent Application Publication No. 2003-209188 discloses a technique regarding a trench capacitor in which a trench is formed in a semiconductor substrate for roughening.

### SUMMARY OF THE INVENTION

As described above, a semiconductor device having a large storage capacity has been achieved by a combination of a capacitor over bit line (COB) structure or a hemispherical silicon grain (HSG) structure, which increases an electrode area of a capacitor even in a small area of the capacitor, and a technique such as a high-dielectric film. However, a decrease in the size of a memory cell limits the size of a cylindrical capacitor structure. More specifically, a cylindrical capacitor structure needs to have a smaller diameter. This also decreases a distance between adjacent cylindrical capacitors. Thus, the aspect ratio of a cylindrical capacitor having a smaller size must further be increased. The present inventors found the following new problems in a cylindrical capacitor having such a large aspect ratio.

The new problems are described below with reference to FIGS. 1A and 1B. FIGS. 1A and 1B are cross-sectional views of a semiconductor device. FIG. 1A is a cross-sectional view when a capacitor hole is formed. FIG. 1B is a cross-sectional view when an upper electrode of a cell capacitor is formed. As illustrated in FIG. 1A, a capacitor hole for forming a cylindrical cell capacitor is bored in a silicon nitride film 17 and an interlayer insulating film 18. The capacitor hole is connected to a diffusion layer (not shown) of a cell transistor via a polysilicon plug 16.

When the capacitor hole has a large aspect ratio, the capacitor hole has a vase-like shape instead of a cylindrical shape as illustrated in FIG. 1A. An upper hole portion having a depth of h from the top surface of the interlayer insulating film 18 is substantially perpendicular to the top surface of the interlayer insulating film 18. The diameter of the upper hole portion is equal to a design diameter R. A portion under the upper hole portion has a so-called bowing shape having a diameter R1 larger than the design diameter R. This portion tapers down to the bottom of the capacitor hole. The bottom of the capacitor hole has a diameter slightly smaller than the design diameter R. The upper hole portion substantially perpendicular to the top surface of the interlayer insulating film 18 is hereinafter referred to as a straight portion. The tapered portion under the straight portion having a diameter R1 larger than the design diameter R is hereinafter referred to as a bowing portion.

An amorphous silicon layer 19 is formed in the capacitor hole as a lower electrode. HSGs 19b are grown in the amorphous silicon layer 19. Then, a capacitive dielectric film 20 is formed on the amorphous silicon layer 19. Then, an upper electrode 21 is formed on the capacitive dielectric film 20. When the upper electrode 21 is formed, a reactant gas is supplied to the capacitor hole through the straight portion. The reactant gas enters a central space surrounded by HSGs growing from the sidewall of the capacitor hole and a circumferential space among adjacent HSGs along the sidewall. However, because the straight portion through which the reactant gas flows has a small opening size, the central space has a small cross-section. Thus, parts of the upper electrode 21 on HSGs growing oppositely from the sidewall come into contact with each other in the straight portion in the course of the formation of the upper electrode 21. This contact partly blocks the flow pass of the reactant gas and reduces the reactant gas flowing into the downstream region.

This makes the reactant gas flow ununiform. Thus, the upper electrode 21 is partly not formed on the surface of HSGs in the capacitor hole, or the thickness of the upper electrode 21 becomes ununiform. Consequently, the upper electrode 21 poorly covers the HSGs. Part of the roughened surface of the lower electrode is not covered with the upper electrode 21 and does not function as a capacitor. When the straight portion having a small opening size is completely blocked by the upper electrode 21, the reactant gas does not flow into the capacitor hole. Therefore, a void or a poor connection occurs in the capacitor hole. This reduces the capacitance. As described above, because the straight portion, which is an entrance to the capacitor hole, has a small opening size, the straight portion is initially blocked by the upper electrode 21. This causes insufficient formation of the upper electrode 21 in the capacitor hole and a decrease in capacitance. These problems also occur in the formation of the capacitive dielectric film 20.

It is therefore an object of the present invention to provide a method for manufacturing a semiconductor device that can prevent a decrease in the capacitance of a cylindrical capacitor because of insufficient formation of an upper electrode of the capacitor resulting from a small opening size of the straight portion.

It is another object of the present invention to provide a semiconductor device that is manufactured by the method and has a sufficient capacitance for stable operation.

According to the present invention, the particle size of HSGs in a straight portion having a small opening size is smaller than the particle size of HSGs in a bowing portion. A smaller particle size of HSGs in the straight portion results in a larger effective opening size when a capacitive dielectric film and an upper electrode film are formed. A larger effective opening size can improve the flow of a reactant gas, achieve improved coverage of HSGs with a capacitive dielectric film and an upper electrode, and provide a certain capacitance. This can provide a semiconductor device that operates stably and a method for manufacturing the semiconductor device.

The present invention basically employs the following technology to solve the problems described above. It is a matter of course that the present invention also encompasses any modified technology without departing from the gist of the technology.

A semiconductor device according to the present invention includes a cylindrical capacitor, wherein the size of HSGs formed in a straight portion of the cylindrical capacitor is smaller than the size of HSGs formed in a bowing portion of the cylindrical capacitor.

In a semiconductor device according to the present invention, the effective opening size of the straight portion may be at least twice the thickness of a capacitive dielectric film.

In the semiconductor device according to the present invention, the effective opening size of the straight portion may be at least twice the total thickness of a capacitive dielectric film and a lower metal film of an upper electrode.

In the semiconductor device according to the present invention, the straight portion may be a region substantially perpendicular to a main surface of a semiconductor substrate, the region starting from the upper end of a lower electrode.

In the semiconductor device according to the present invention, the bowing portion may have the largest opening size at a height of 70% to 80% of the height of the cylindrical capacitor.

In the semiconductor device according to the present invention, the size of HSGs formed in the straight portion of the cylindrical capacitor may be lower than the size of HSGs formed in the bowing portion by 5 to 15 nm.

A method for manufacturing a semiconductor device according to the present invention includes the steps of forming an interlayer insulating film on a semiconductor substrate, forming a cylindrical hole in the interlayer insulating film, forming an amorphous semiconductor layer as a lower electrode of a capacitor over the entire surface of the semiconductor substrate, introducing an impurity into a straight portion of the amorphous semiconductor layer, seeding the surface of the amorphous semiconductor layer, and roughening the surface of the amorphous semiconductor layer so that the size of HSGs in the straight portion is smaller than the size of HSGs in a bowing portion.

In the method for manufacturing a semiconductor device according to the present invention, the step of introducing an impurity includes introducing an impurity into the straight portion of the amorphous semiconductor layer by oblique ion implantation.

In the method for manufacturing a semiconductor device according to the present invention, the oblique ion implantation includes implanting an n-type impurity at an angle of 15° to 70°.

The method for manufacturing a semiconductor device according to the present invention may further includes applying a resist to a region under the straight portion of the amorphous semiconductor layer before introducing an impurity.

In a method for manufacturing a semiconductor device according to the present invention, the particle size of HSGs in the straight portion near the opening of the cylindrical capacitor is smaller than the particle size of HSGs in the bowing portion. A smaller particle size of HSGs in the straight portion results in a larger effective opening size. This increases the opening area through which a reactant gas is introduced. An increase in the reactant gas flow improves the coverage of HSGs. Thus, the entire surface of an amorphous silicon film can be used as a lower electrode. This ensures sufficient capacitance. This can provide a semiconductor device that has a sufficient capacitance for stable operation and a method for manufacturing the semiconductor device.

### BRIEF DESCRIPTION OF THE DRAWINGS

FIG. 1A is a cross-sectional view of a related semiconductor device when a capacitor hole is formed;

FIG. 1B is a cross-sectional view of a related semiconductor device when an upper electrode of a cell capacitor is formed;

FIG. 2 is a cross-sectional view of a cylindrical capacitor according to a first embodiment of the present invention;

FIG. 3 is a cross-sectional view of the cylindrical capacitor according to the first embodiment of the present invention in a first step;

FIG. 4 is a cross-sectional view of a cylindrical capacitor according to the first embodiment of the present invention in a second step;

FIG. 5 is a cross-sectional view of the cylindrical capacitor according to the first embodiment of the present invention in a third step;

FIG. 6 is a cross-sectional view of the cylindrical capacitor according to the first embodiment of the present invention in a fourth step;

FIG. 7 is a cross-sectional view of the cylindrical capacitor according to the first embodiment of the present invention in a fifth step;

FIG. 8 is a graph of the effective opening size as a function of the ion implantation dose;

FIG. 9 is a graph of the relative cell capacitance as a function of the ion implantation dose;

FIG. 10 is a graph of the relative yield rate in terms of information retention time as a function of the ion implantation dose; and

FIG. 11 is a cross-sectional view of a cylindrical capacitor according to a second embodiment of the present invention in an intermediate step.

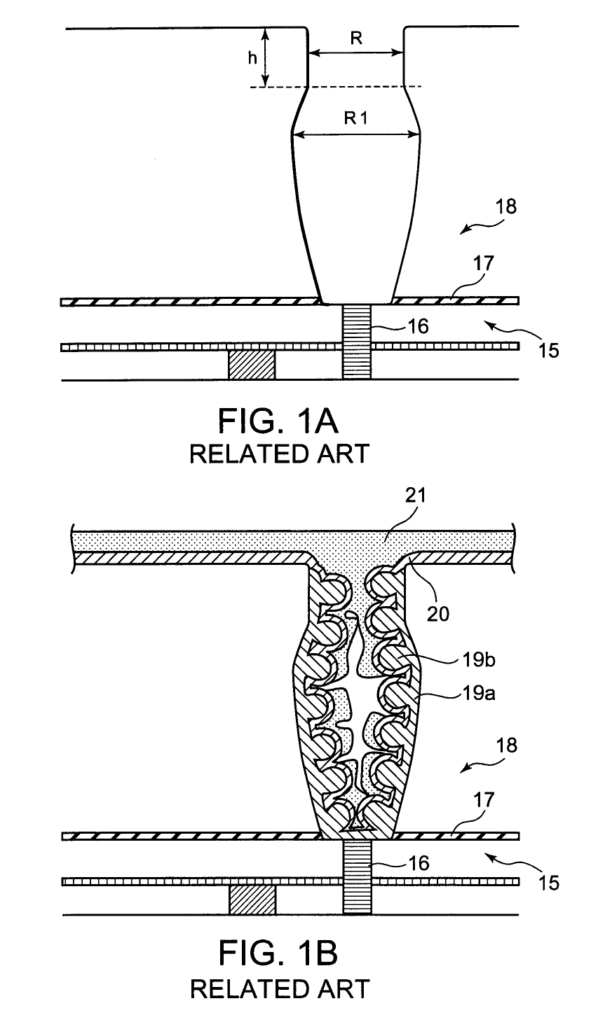

### DESCRIPTION OF THE PREFERRED EMBODIMENTS

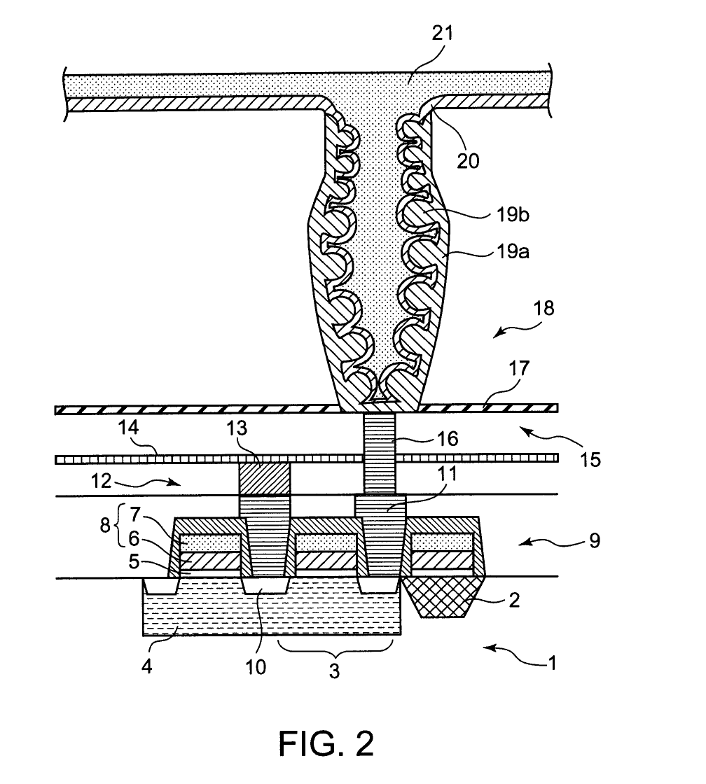

A semiconductor device according to the present invention and a method for manufacturing the semiconductor device will be described below with reference to FIGS. 2 to 11.

As illustrated in FIG. 2, a device isolation region 2 is formed in a semiconductor substrate 1. Then, a gate transistor 3 of a memory cell is formed in the semiconductor substrate 1. The memory cell transistor 3 comprises gate insulating films 5 formed on a p-well region 4, gate electrodes 8 formed on the gate insulating films 5, and diffusion layer regions 10. Agate electrode 8 is a laminate of a polycrystalline silicon film 6 and a silicide film 7. The memory cell transistor 3 is covered with a first interlayer insulating film 9. Contact holes reaching the diffusion layer regions 10 are formed by lithography and anisotropic dry etching. Then, polysilicon or amorphous silicon is deposited in the contact holes and is etched back or is subjected to chemical-mechanical polishing (CMP) to form polysilicon plugs 11.

After the polysilicon plugs 11 are formed, a second interlayer insulating film 12 is formed on the first interlayer insulating film 9. A hole is formed in the second interlayer insulating film 12 by lithography and anisotropic dry etching. Then, titanium nitride (TiN) and tungsten (W) are deposited in the hole and are etched back or are subjected to CMP to form a tungsten plug 13. After the tungsten plug 13 is formed, titanium nitride (TiN) and tungsten (W) are deposited on the second interlayer insulating film 12. A bit line 14 is formed by lithography and anisotropic dry etching.

The bit line 14 is covered with a third interlayer insulating film 15. A contact hole reaching a polysilicon plug 11 connected to a diffusion layer region 10 is formed by lithography and anisotropic dry etching. Then, polysilicon or amorphous silicon is deposited in the contact hole and is etched back or is subjected to CMP to form a polysilicon plug 16. Then, a silicon nitride film 17 is formed on the third interlayer insulating film 15. Then, a plasma oxide film 18 having a thickness of 2 to 4 μm is deposited on the silicon nitride film 17. The following steps are described with reference to FIGS. 2 to 6.

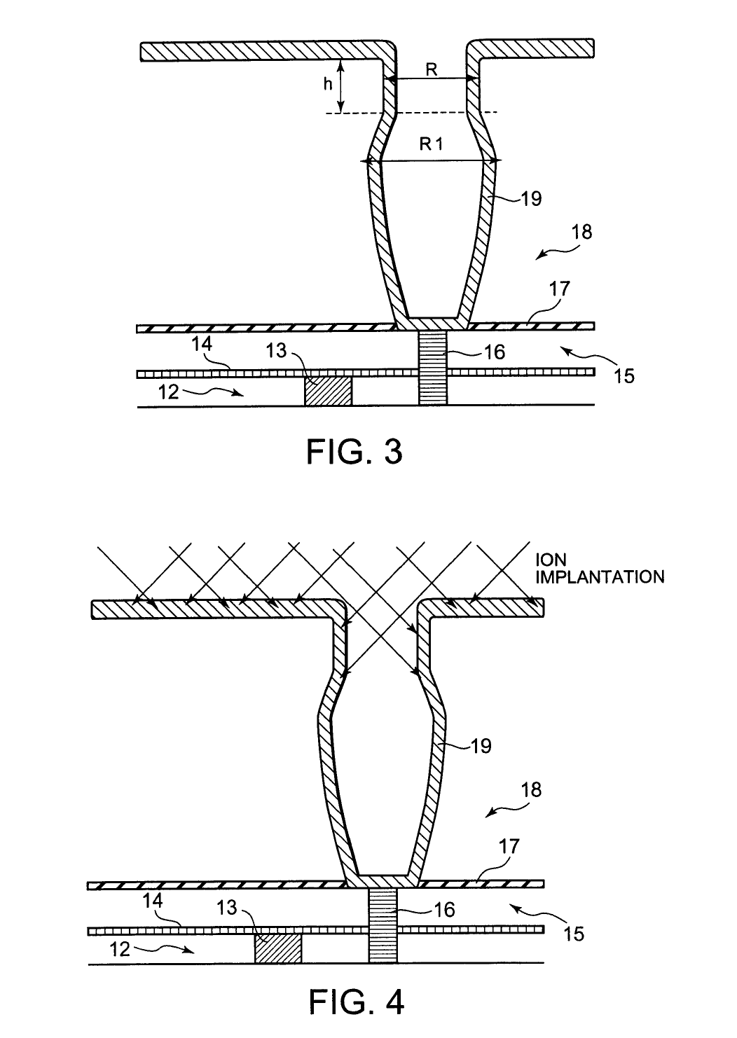

As illustrated in FIG. 3, the plasma oxide film 18 and the silicon nitride film 17 are etched by lithography and anisotropic dry to form a cylindrical capacitor hole. An amorphous silicon layer 19 containing a low concentration of phosphorus, which is to serve as a lower electrode, is deposited on the plasma oxide film 18 at a temperature of 500° C. to 550° C. The amorphous silicon layer 19 has a thickness of one quarter of the opening size or less, which is 20 to 50 nm. The amorphous silicon layer 19 becomes a cylindrical electrode constituting a lower electrode of a cylindrical capacitor.

When the capacitor hole has an aspect ratio of 15 or more, the capacitor hole has a vase-like shape instead of a cylindrical shape. An upper hole portion having a depth of h from the top surface of the plasma oxide film 18 is substantially perpendicular to the top surface of the plasma oxide film 18 and has a diameter substantially equal to a design diameter R. The upper hole portion is hereinafter referred to as a straight portion. A bowing portion under the straight portion has a diameter R1 larger than the design diameter R and tapers down to the bottom of the capacitor hole. For example, when the plasma oxide film 18 has a thickness of 3.2 μm and the opening size is 155 nm, the aspect ratio is about 20. According to the present embodiment, the straight portion has a height h of 0.2 to 0.3 μm. The bowing portion has the largest diameter R1 at a height of 70% to 80% of the height of the capacitor hole. The diameter R1 is about 20%-30% higher than the design diameter R and is about 190 nm.

Then, as illustrated in FIG. 4, the amorphous silicon layer 19 remained over the entire surface of the plasma oxide film 18 is doped with an impurity, for example, a dose of 1×10¹⁴ atoms/cm² of phosphorus by ion implantation at an incident angle of 30°, an accelerating voltage of 20 keV, and a four-way step. The amorphous silicon layer 19, which becomes a lower electrode, is doped with an impurity at the concentration depending on the vertical position. In this embodiment, the incident angle of the ion implantation is set so that the amorphous silicon layer 19 at the straight portion is doped with an impurity and the bowing portion is not doped with an impurity.

When the incident angle of the ion implantation is too large, the amorphous silicon layer 19 at part of the straight portion is not doped with an impurity. When the incident angle of the ion implantation is slightly small, part of the bowing portion is doped with an impurity. However, since the aspect ratio is large, the position error in the vertical direction is negligible. The incident angle of the ion implantation therefore is preferably slightly smaller than the set point. The incident angle of the ion implantation depends on the aspect ratio and is preferably 15° to 70°.

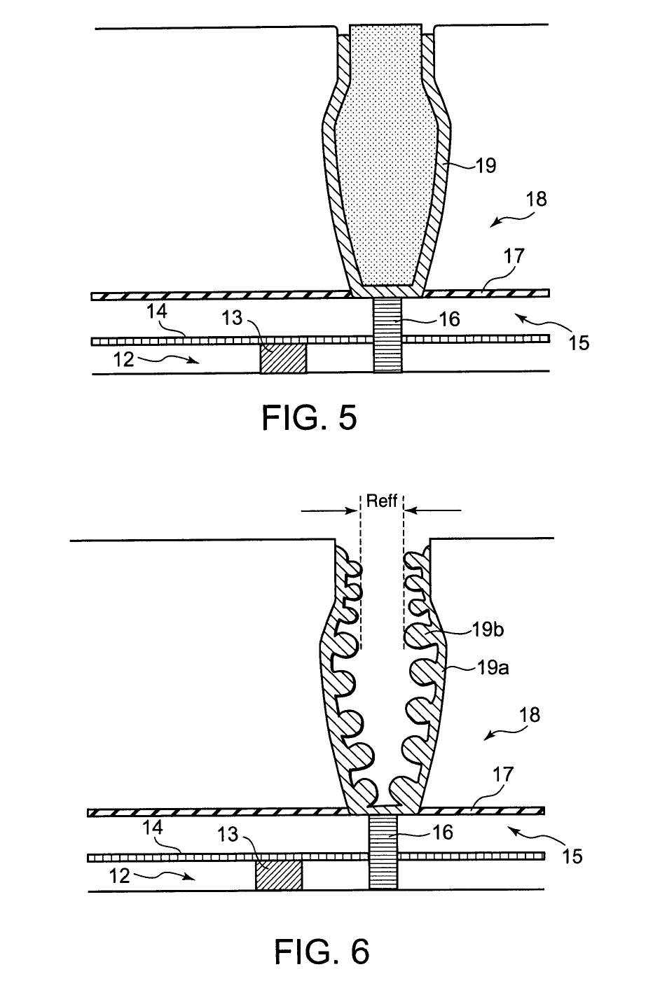

Then, as illustrated in FIG. 5, a photoresist is left only in the capacitor hole by photolithography. The amorphous silicon layer 19 is etched back so that the top end of the amorphous silicon layer 19 is lower than the top end of the capacitor hole by 30 nm. The amorphous silicon layer 19 is etched back to separate each amorphous silicon layer 19 in the adjacent capacitor holes. Each separated amorphous silicon layer 19 serves as a lower electrode (cylindrical electrode) of the corresponding cylindrical capacitor. Then, the photoresist is removed with a hot sulfuric acid/hydrogen peroxide mixture.

Then, as illustrated in FIG. 6, the amorphous silicon layer 19 is washed and a natural oxide film is removed. Subsequently, microcrystal grains are formed on the surface of the lower electrode at a temperature of 550° C. to 570° C. with an HSG-Si apparatus using a seeding gas of monosilane or disilane. Then, the microcrystal grains are grown by annealing to form HSGs 19b. The amorphous silicon layer 19 is converted into HSGs 19b and a silicon layer 19a along the sidewall of the capacitor hole. The HSGs 19b and the silicon layer 19a constitute the lower electrode. The HSGs roughen the surface of the lower electrode and increase the surface area of the lower electrode.

HSGs in the bowing portion, at which the amorphous silicon layer 19 contains fewer impurities, grow larger. HSGs in the straight portion, at which the impurity concentration is higher because of ion implantation, grow smaller. HSGs growing from the sidewall form a space in the center of the capacitor hole. The diameter of the space is hereinafter referred to as an effective opening size Reff. Because the HSGs in the straight portion are smaller, the effective opening size Reff of the straight portion is larger. FIG. 8 illustrates the effective opening size as a function of the ion implantation dose. FIG. 8 illustrates mean values (circles) and variations of the effective opening size Reff.

When the initial opening size R is 155 nm, the silicon layer 19a is 15 nm, and the HSG size in the absence of ion implantation is 40 nm, the effective opening size Reff is 45 nm. Ion implantation decreases the HSG size and increases the effective opening size Reff. When the ion implantation dose is 1×10¹⁴ atoms/cm², the HSG size is 35 nm and the effective opening size Reff is increased to 55 nm. When the ion implantation dose is 2×10¹⁵ atoms/cm², the HSG size is 25 nm and the effective opening size Reff is increased to about 75 nm.

The HSG size varies widely. For example, variations are ±10 nm at a mean HSG size of 40 nm. Ion implantation decreases the mean HSG size and thereby decreases the variations. Thus, the mean particle size of HSGs in the straight portion, which is subjected to ion implantation, is 5 to 15 nm smaller than that in the bowing portion, which is not subjected to ion implantation. A reactant gas is introduced into a central space having an effective opening size and a circumferential space among adjacent HSGs along the sidewall of the capacitor hole. In order to introduce the reactant gas efficiently through a minimum cross-section, the effective opening sizes in the straight portion and the bowing portion needs to be as equal as possible.

During the formation of an upper electrode 21, a blockage occurs initially at a portion having the smallest effective opening size and thereby reduces the reactant gas flow. Accordingly, the effective opening size Reff must be larger than a certain value. The effective opening size Reff is not less than the effective opening size Reff at which a capacitive dielectric film 20 described below can sufficiently be formed. Preferably, the effective opening size Reff is not less than the effective opening size Reff at which a lower metal layer (not shown) of the upper electrode 21 can also sufficiently be formed. For example, when the thickness of a capacitive dielectric film 20 is 10 to 15 nm, the effective opening size Reff is more than twice the thickness of a capacitive dielectric film 20 and may be at least 40 nm. More preferably, the effective opening size Reff is more than twice the total thickness of the capacitive dielectric film 20 (10 to 15 nm) and a lower metal layer (10 nm) of the upper electrode 21 and may be at least 55 nm so that the lower metal layer (10 nm) can also satisfactorily cover HSGs.

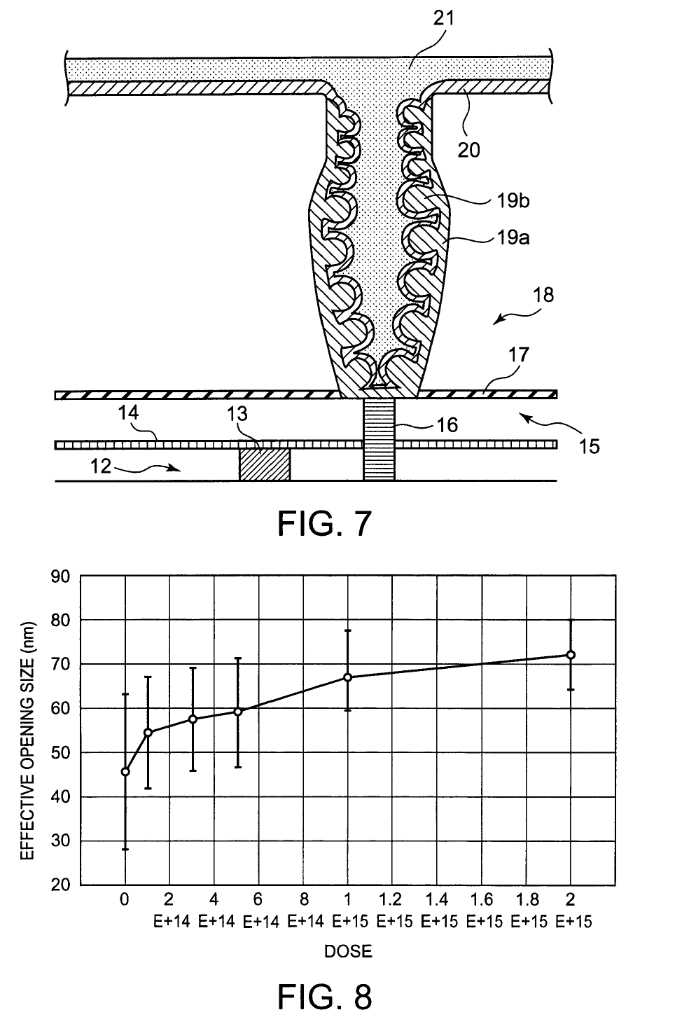

Then, as illustrated in FIG. 7, to prevent the depletion and reduce the resistance of the amorphous silicon layer 19a and the HSGs 19b, which serve as the lower electrode of the capacitor, the amorphous silicon layer 19a and the HSGs 19b are doped with an n-type impurity, for example, 5×20 atoms/cm³ of phosphorus in a low pressure CVD furnace. Subsequently, the capacitive dielectric film 20 having a thickness of 10 to 15 nm is formed on the lower electrode by low pressure CVD and is oxidized with an oxidizing gas. Then, the upper electrode 21 is deposited on the capacitive dielectric film 20 to form a capacitor. The upper electrode 21 includes, for example, a titanium nitride film having a thickness of 10 nm as the lower metal layer (not shown) and a tungsten film as an upper metal layer (not shown). Preferably, the straight portion keeps the effective opening size until the lower metal layer completely covers the capacitive dielectric film 20 so that a deposition gas of the lower metal layer can flow into the capacitor hole.

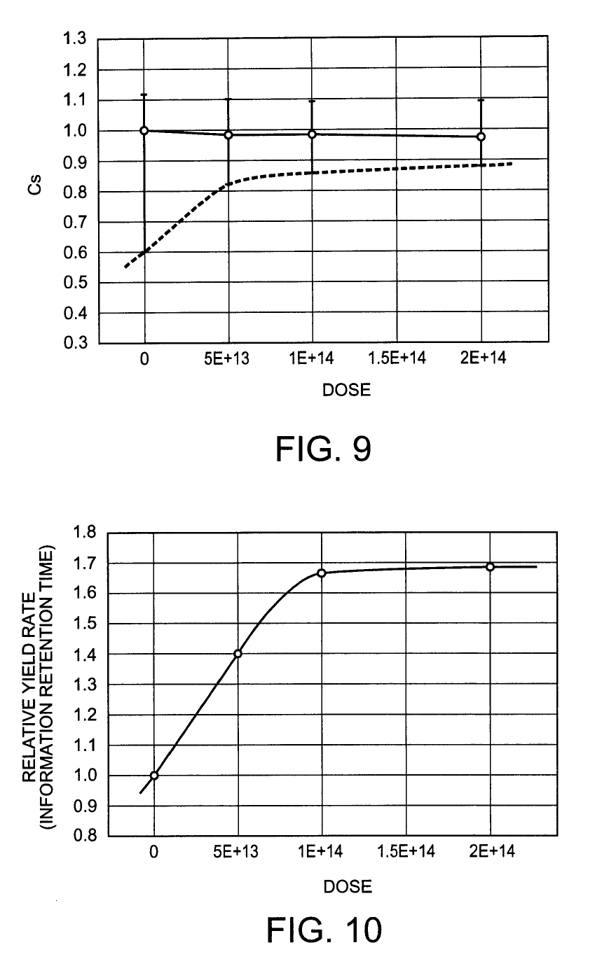

FIG. 9 illustrates mean values (circles) and variations of the relative cell capacitance Cs as a function of the ion implantation dose. FIG. 10 illustrates the relative yield rate in terms of information retention time as a function of the ion implantation dose. As illustrated in FIG. 9, the mean value and the maximum value of the cell capacitance Cs decrease about 1% to 2% by ion implantation. The minimum value of the relative cell capacitance Cs is greatly increased from 60% to 85%-90% by ion implantation. In proportion to the minimum value of the relative cell capacitance Cs, as illustrated in FIG. 9, the yield rate in terms of the information retention time is also greatly increased by ion implantation.

As described above, the cell capacitor is assumed to have an opening size of 155 nm and a depth of 3.2 μm, and have a straight portion 0.2 μm in length. The straight portion is 6% (0.2/3.2) of the cell capacitor. When the straight portion has a HSG size of 40 nm in the absence of ion implantation and 35 nm in the presence of ion implantation, ion implantation decreases the surface area of HSGs by about 1%. Accordingly, the mean value and the maximum value of the relative cell capacitance Cs decreases slightly by ion implantation.

The minimum value of the relative cell capacitance Cs depends on the effective opening size Reff. In the absence of ion implantation, the smallest effective opening size is about 25 nm. In this case, when the thickness of the capacitive dielectric film 20 reaches 10 nm, the remaining effective opening size is 5 nm. Thus, in the formation of the lower metal layer of the upper electrode 21, a reactant gas is partly blocked. Thus, the lower metal layer of the upper electrode 21 cannot cover the entire surface of the HSGs. Since the total surface area of the HSGs is not fully utilized, the relative cell capacitance Cs decreases greatly and varies widely in the minimum direction. The variations of the relative cell capacitance Cs in the maximum direction are about 10% at any ion implantation dose. However, the relative cell capacitance Cs varies very widely in the minimum direction and is about 60% (40% smaller than the mean value) in the absence of ion implantation.

The variations of the relative cell capacitance Cs in the minimum direction is almost the same as those in the maximum direction at an ion implantation dose of 1×10¹⁴ atoms/cm² or more. At an ion implantation dose of 1×10¹⁴ atoms/cm² or more, the variations of the relative cell capacitance Cs are almost the same in the maximum direction and in the minimum direction, and the relative yield rate in terms of the information retention time keeps an almost constant level. In other words, at an ion implantation dose of 1×10¹⁴ atoms/cm² or more, the effective opening size Reff is sufficient, and the upper electrode 21 satisfactorily covers HSGs and is formed excellently. Thus, the surface area of the HSGs is fully utilized. The upper electrode 21 does not block the opening at the straight portion until it covers the entire surface of the HSGs. According to the graph illustrated in FIG. 8, the effective opening size Reff is 40 nm at the minimum and 55 nm on average at an ion implantation dose of 1×10¹⁴ atoms/cm².

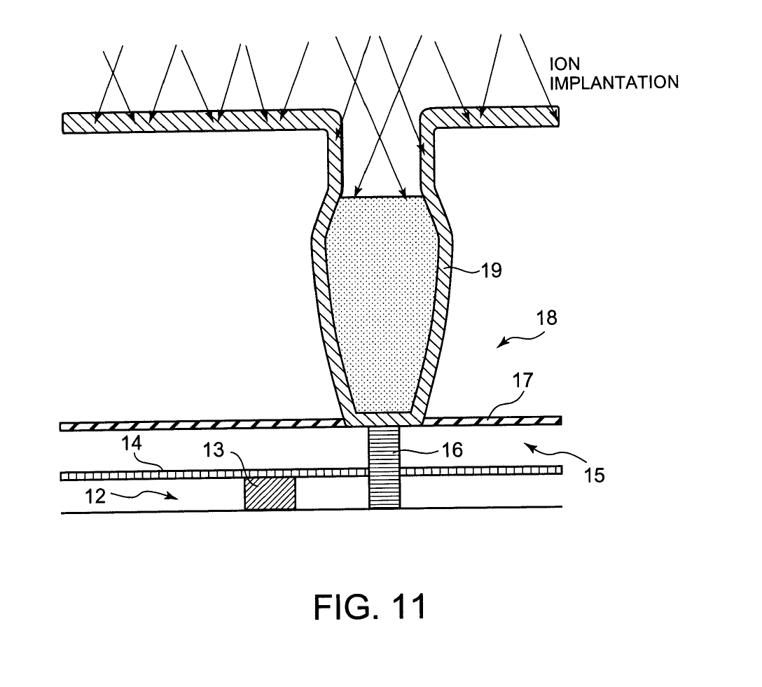

FIG. 11 is a cross-sectional view of a cylindrical capacitor manufactured by another method. As illustrated in FIG. 3, an amorphous silicon layer 19 having a thickness of one quarter of the opening size or less, which is 20 to 50 nm, is deposited on the plasma oxide film 18 at a temperature of 500° C. to 550° C. Subsequently, ion implantation is performed while the amorphous silicon layer 19 is remained over the entire surface of the plasma oxide film 18 and a photoresist is left only in the capacitor hole by photolithography. In this case, the photoresist is not remained at the straight portion and is remained at the bowing portion. As a consequence, as in the method described above, only the straight portion is doped with an impurity. Then, the photoresist is removed with a hot sulfuric acid/hydrogen peroxide mixture. Then, subsequent steps are performed in the same manner as the etchback by photolithography illustrated in FIG. 5 and the subsequent steps described above.

According to the present invention, the straight portion of the cylindrical capacitor is doped with a high concentration of impurity. The straight portion doped with an impurity has a smaller HSG size. A smaller HSG size can result in an increase in the effective opening size at the straight portion. The increased effective opening size allows a reactant gas to be introduced smoothly and allows the capacitive dielectric film and the upper electrode film to cover HSGs satisfactorily. The roughened surface of the lower electrode is evenly covered with the upper electrode. Thus, the surface area of HSGs is fully utilized to provide a desired cell capacitance. The present invention can provide a semiconductor device that has a sufficient cell capacitance for preventing a poor connection and ensuring stable operation, and a method for manufacturing the semiconductor device.

While the present invention is specifically described according to the embodiments, the present invention is not limited to these embodiments and may be modified without departing from the gist of the present invention. It is a matter of course that the present invention also encompasses these modifications.

What is claimed is:

1. A semiconductor device including a cylindrical capacitor, wherein:
a size of hemispherical silicon grains (HSGs) formed in a straight portion of the cylindrical capacitor is smaller than a size of HSGs formed in a bowing portion of the cylindrical capacitor.

2. The semiconductor device according to claim 1, wherein:
an effective opening size of the straight portion is at least twice a thickness of a capacitive dielectric film.

3. The semiconductor device according to claim 1, wherein:
an effective opening size of the straight portion is at least twice a total thickness of a capacitive dielectric film and a lower metal film of an upper electrode.

4. The semiconductor device according to claim 1, wherein:
the straight portion is a region substantially perpendicular to a main surface of a semiconductor substrate, the region starting from an upper end of a lower electrode.

5. The semiconductor device according to claim 1, wherein:
the bowing portion has the largest opening size at a height of 70% to 80% of a height of the cylindrical capacitor.

6. The semiconductor device according to claim 1, wherein:
a size of HSGs formed in a straight portion of the cylindrical capacitor is lower larger than a size of HSGs formed in the bowing portion by 5 to 15 nm.

7. A method for manufacturing a semiconductor device, comprising the steps of:
forming an interlayer insulating film on a semiconductor substrate;
forming a cylindrical hole in the interlayer insulating film;
forming an amorphous semiconductor layer as a lower electrode of a capacitor over an entire surface of the semiconductor substrate;
introducing an impurity into a straight portion of the amorphous semiconductor layer;
seeding a surface of the amorphous semiconductor layer; and
roughening the surface of the amorphous semiconductor layer so that a size of HSGs in the straight portion is smaller than a size of HSGs in a bowing portion.

8. The method for manufacturing a semiconductor device according to claim 7, wherein:
the step of introducing an impurity comprises introducing an impurity into the straight portion of the amorphous semiconductor layer by oblique ion implantation.

9. The method for manufacturing a semiconductor device according to claim 8, wherein:
the oblique ion implantation comprises implanting an n-type impurity at an angle of 15° to 70°.

10. The method for manufacturing a semiconductor device according to claim 7, further comprising:
applying a resist to a region under the straight portion of the amorphous semiconductor layer before introducing an impurity.
